(19) United States
(12) Patent Application Publication
(10) Pub. No.: US 2012/0224337 A1
(43) Pub. Date: Sep. 6, 2012

(54) COMPACT COMMUNICATION SYSTEM

(76) Inventors: Joel Cristopher BODINE, Leesburg, VA (US); Brian Keith EVERHART, Shepherdstown, WV (US); Nicholas Allen HICKMAN, Great Falls, VA (US); Marc SENDICH, Reston, VA (US); Melvin Winthrop CLARKE, Vienna, VA (US)

(21) Appl. No.: 13/041,067

(22) Filed: Mar. 4, 2011

(51) Int. Cl. H05K 7/00

(52) U.S. Cl. 361/752

(57) ABSTRACT

A communication device includes a top wall, a bottom wall and a plurality of side walls including a front wall, a plurality of input ports, at least one input port provided with power, a least one output port, a printed circuit board, and a plurality of components board mounted on the printed circuit board. The components include an input/output panel, a switch, a router, a power supply, and a power-over-ethernet injector. The components are electrically connected to one another through a backplane on the printed circuit board.

### FIELD OF THE INVENTION

The present invention relates to mobile communications and networking devices and more particularly to mobile, modular devices providing either unsecure, secure or a combination of unsecure and secure communications from remote locations to other remote locations or to central site locations.

### BACKGROUND OF THE INVENTION

Electronic communications devices have played an increasingly significant role in business, personal and government operations since their original inception. As the requirement for increased integration of types of communications systems, such as voice, data and video, has occurred, so too has the requirement for integrated systems that allow for these devices to be deployed in increasingly mobile fashion in support of both secure and non-secure communications. Traditionally, this requirement has been met by either the placement of commercially available equipment into mobile transit cases or brief cases (with multiple, independent components wired together via external cables and powered individually), which can achieve the required communications functionality. However, the reliance on off the shelf components causes a system having high capabilities to be too large for rapid physical transportation. When off the shelf components are integrated into custom single-purpose products, the resulting system can be small and light but limited in their application and ability to hot-swap individual components or meet the physical separation requirements of combined secure/non-secure communications. Therefore, there is a tradeoff between capability and mobility of a system.

There presently exists a need for extremely small, highly mobile and adaptable devices allowing for communications users to deploy such systems in support of mobile, emergency response or military applications, including the ability to provide for physical separation of secure/non-secure communications components when or if required.

There is a need for a compact communications device capable of providing the ability to accept secure/classified user communications, including voice, data and video, the means to encrypt or secure such user communications through external encryption capabilities, the means to optimize the secure voice, data and video communications for transmission across a remote reachback communications link, the ability to physically add separate accessories to provide for self-powered operations and the ability to physically separate modular accessories to facilitate the ability to provide physical separation between secure and non-secure communications components during actual operations.

It is an object of the invention to provide a communication device having board mounted internal components to reduce the size of the device.

It is another object of the invention to provide a communication device having a large number of input ports in a compact configuration to facilitate transport of the device.

It is still another object of the invention to provide a communication system having several modules that may be used together or separately.

These and other objects of the invention will be apparent to one of ordinary skill in the art after reading the disclosure of the invention.

### SUMMARY OF THE INVENTION

A communication device includes a top wall, a bottom wall and a plurality of side walls including a front wall, a plurality of input ports, at least one input port provided with power, a least one output port, a printed circuit board, and a plurality of components board mounted on the printed circuit board. The components include an input/output panel, a switch, a router, a power supply, and a power-over-ethernet injector. The components are electrically connected to one another through a backplane on the printed circuit board.

A communication system including a main module, the main module having a top wall, a bottom wall and a plurality of side walls including a front wall, a plurality of input ports, at least one input port provided with power, a least one output port, a printed circuit board, and a plurality of components board mounted on the printed circuit board. The components includes an input/output panel, a switch, a router, a power supply, and a power-over-ethernet injector. The components are electrically connected to one another through a backplane on the printed circuit board. A battery module has a power transfer connector for supplying power to the main module.

### BRIEF DESCRIPTION OF THE FIGURES

FIG. 1 is a perspective view of the communication system;

FIG. 2 depicts the main module of the system;

FIG. 3 is a schematic diagram of the board-level components of the main module;

FIG. 4 depicts the secondary module of the system;

FIG. 5 depicts the battery module of the system; and

FIG. 6 is an exploded bottom perspective view of the components of the system.

### DETAILED DESCRIPTION OF THE INVENTION

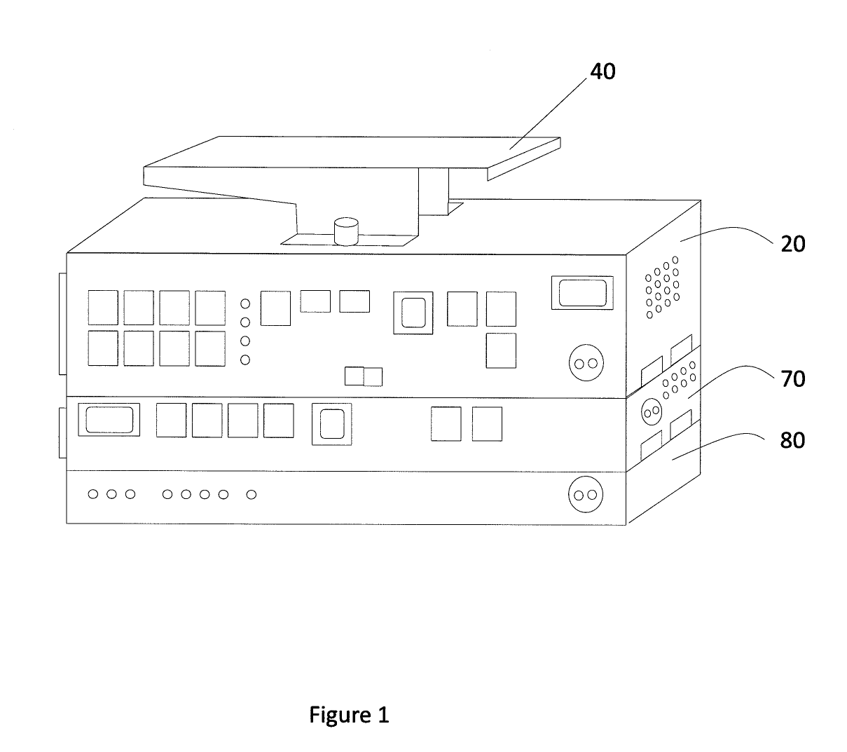

The system depicted in FIG. 1 has a main module 20, a router module 70 and a battery module 80. The modules are releasable attached to one another, allowing the quick and easy replacement of one module for another or the attachments of various modules together to suit the needs of a particular application. On top of the main module is a removable bracket 40. The removable bracket is intended to retain an inline network encryptor (INE) for use in transmitting classified data. Each of these components is discussed separately.

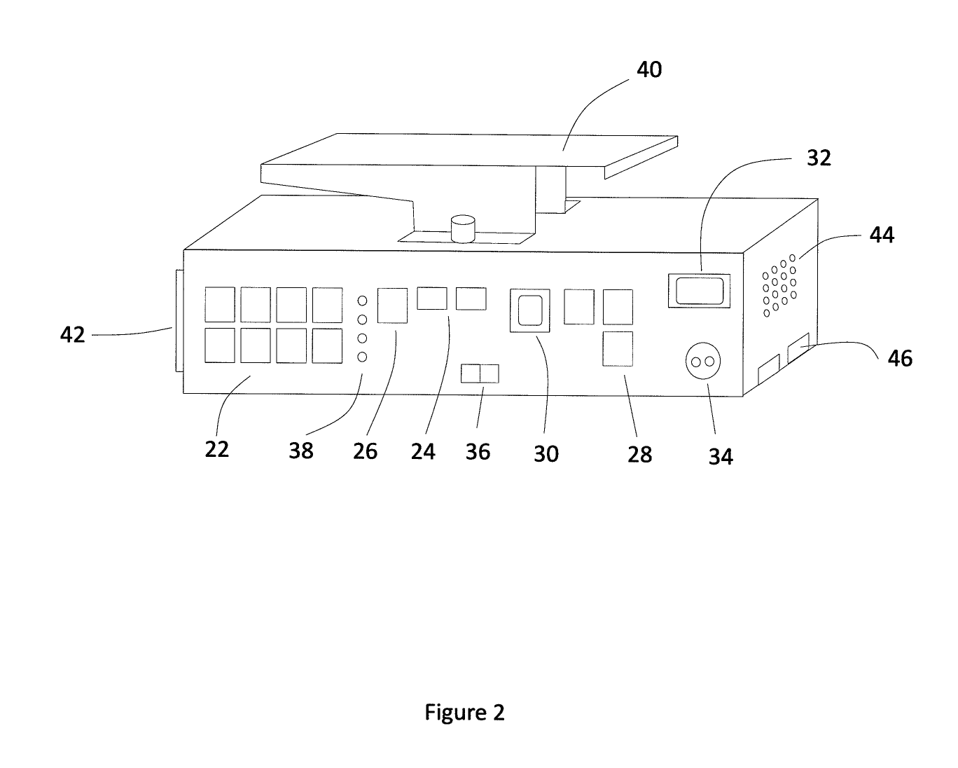

As shown in FIG. 2, the main module 20 is a self-enclosed device capable of being deployed without any other modules or accessories. All input/output communications ports and status indicators are located on the front panel, including the wide-range filtered DC power input. There are at least eight (8) RJ-45 LAN user input ports 22, three (3) of which feature Power over Ethernet (PoE) to allow for the deployment of Voice over IP (VoIP) phones, two (2) fiber-optic input ports 24, one (1) RJ-45 LAN output port 26 for connection to a network, an external encryption device such an the in-line network encrytpor retained by the bracket 40 or other upstream main modules and featuring PoE support to support encryption devices which can be powered through PoE LAN connections. In addition, the main module includes a series of console ports 28 to access the internal components for configuration purposes, a zeroization button 30 allowing for the wiping of the memory of the internal router in the event of such a requirement, a power switch 32 for turning the power on and off, a power input port 34 allowing the main unit to receive power from an external source, and a network acceleration bypass switch 36, allowing the user to enable or disable the internal acceleration feature, which will be discussed later, a series of status indicator LEDs 38 and a filtered air intake 42, with removable filter, and air exhaust 44 on opposite sides of the unit. The unit features a quick attach/release mechanism 46 on the sides of the unit, allowing other modules to be attached to the underside of the unit, which will be described in more detail later.

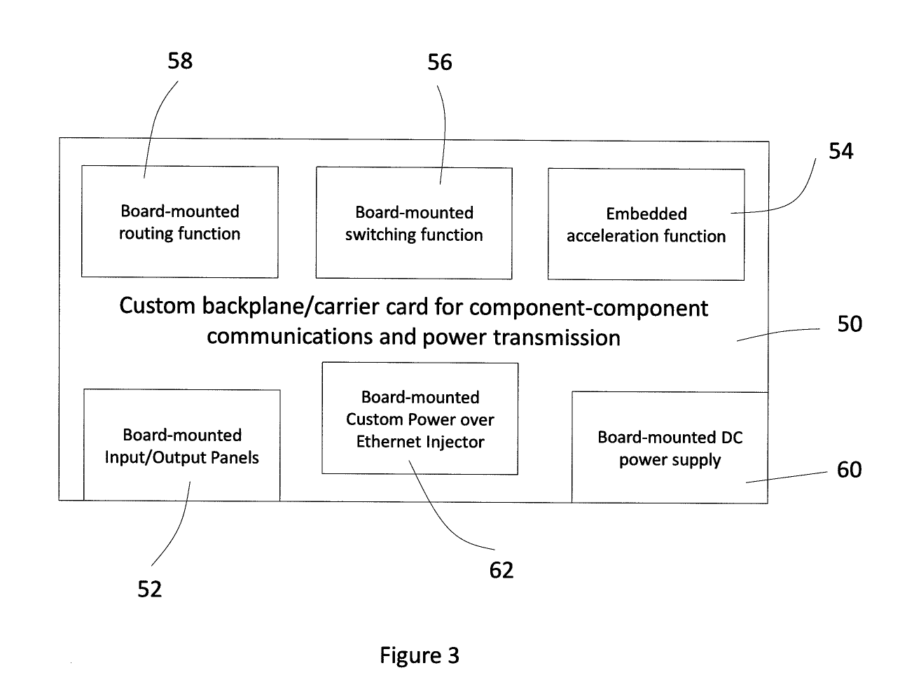

The small size of the unit, having dimensions no greater than eleven inches by five inches by three inches in height, or a volume of no greater than one hundred sixty five cubic inches, is primarily the result of the internal design of the unit, as shown in the schematic view of FIG. 3. The design includes a high level of board mounted components on a custom backplane/carrier board 50. In the past, typical communications devices that integrated separate Commercial-Off-The-Shelf (COTS) devices (individual boxes/units) into a single unit did so with the need for multiple cables to be connected between devices for power and device-to-device communications. For instance, an off-the-shelf switch included its own power supply and interface. The connection of a component to the board 50 without its own power supply, interface or power cables is referred to as being “board mounted.”

The custom backplane/carrier board eliminates the need for powers supplies, interfaces and power cables by directly mounting COTS devices (reduced to the board/component-level), allowing for all communications and power to be directed through the backplane/carrier board. By removing ancillary elements and having just the components attached to the board 50, the overall size of the device is reduced and air flow is improved. A board mounted input/output panel 52 is mounted on the board, allowing for data and power transmission through the various input and output ports described with reference to FIG. 2. An accelerator 54 is also mounted to the board. The accelerator optimizes data for satellite transmission. As discussed later, when data, such as voice over internet, is input that would not need such optimization, the accelerator is bypassed, either through the connections between the ports and components, to be discussed later or by using the accelerator bypass switch 36. The board also includes a switch 56. Although shown as a single components, the switch is best configured as two separate switches. The input ports not having PoE are connected through conductive traces on the board to a first switch, with the first switch then being connected to the accelerator 54 by conductive traces. The accelerator, in turn, is connected to a router 58. The accelerator is an optional component as the system will function completely without one. Those input ports having PoE are connected by conductive traces to a second switch, the second switch then connected to the router 58. The second switch can be physically located on the router. Since the second switch and the routing module act as a single unit, the second switch is still considered “board mounted.” In this manner, the input ports having PoE bypass the accelerator. This is desirable when the signal input through the ports having PoE, such as voice-over-internet, does not need to be optimized by the accelerator module. The main module has a accelerator by pass switch 36, allowing input through the ports not having PoE to still bypass the accelerator.

Additionally, the backplane/carrier board includes a DC power supply 60 for receiving power from an external source, and a custom PoE injection system 62 which allows for the use of smaller internal components (primarily switch and router components that do not have native support for PoE) rather than larger pre-built COTS components having their own built in PoE capabilities. This also reduces the size of the internal DC power supply 60. Additional benefits of the custom backplane/carrier board include an overall reduction in the size of the main module since the space requirement for internal wiring harnesses has been eliminated, the improvement of air-flow, since the elimination of cables allows for a smoother flow of air through the unit, and the reduction of the size of the air intakes and fan. The reliance on board-mounted components allow the dimensions of the board to be no greater than eleven inches by five inches, or the equivalent of an area no greater than fifty five square inches. Also, the board mounted components enable a low-profile front panel having dimensions no greater than eleven inches by three inches, or a surface area no greater than thirty three square inches.

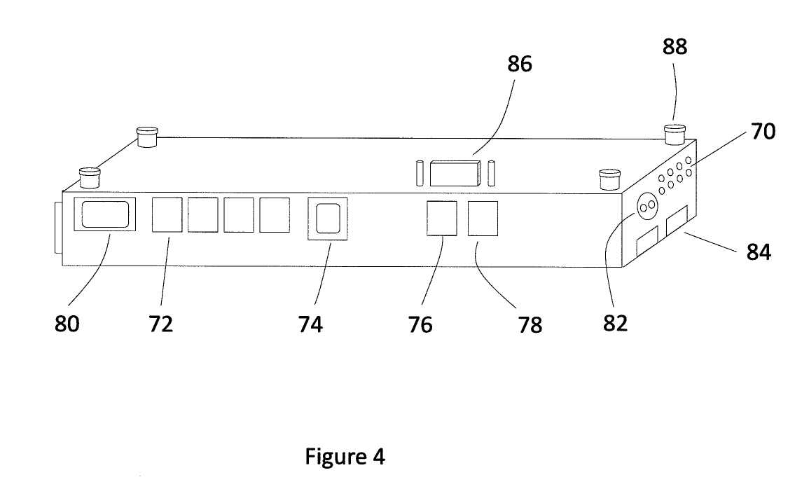

The secondary module shown in FIG. 4 is a self-enclosed device capable of being deployed without any other modules or accessories. All input/output communications ports and status indicators are located on the front panel, with the exception of the wide-range filtered DC power input 82 which is located on the side of the module. This includes four (4) RJ-45 LAN user input ports 72, a zeroization button 74 allowing for the wiping of the memory of the internal router in the event of such a requirement, a console switch 76, and one (1) RJ-45 LAN output port 78 for connection to a network or other upstream devices. In this way, the secondary module has most of the input ports and other features of the main module, but just less in number.

The system also has mechanical connectors 84, and a power transfer connector 86 that mates with a suitable connector on the bottom of the main module to allow power transfer of filtered DC power between the two modules. In addition to the mechanical connectors 84, which are similar to the connectors 46 of the main module, the connection posts 88 are also seen. These features will be described in more detail later. The module also features a filtered air intake, with removable filter, and air exhaust on the sides of the unit. The secondary module can be used in the same manner as the main module, although due to the lower number of ports, the secondary module has less capabilities. When used with the main module, the secondary module is useful for receiving the output of the inline network encryptor and uploading the input to a network through a satellite connection.

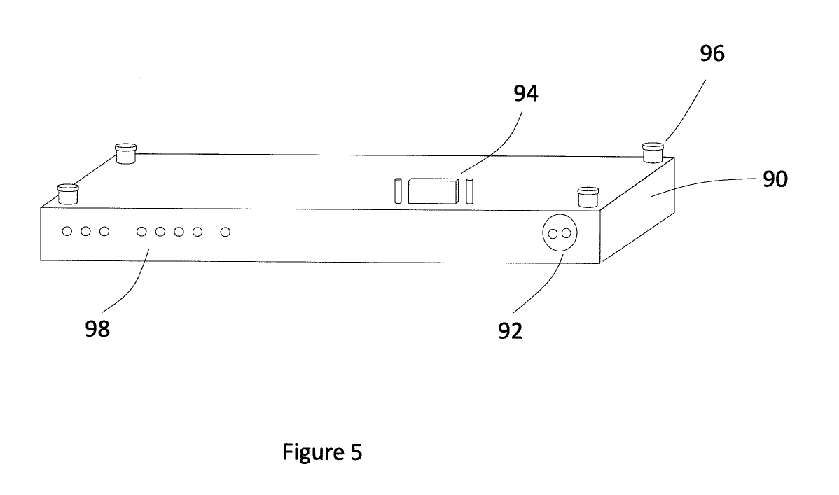

The battery module 90 shown in FIG. 5 is a self-enclosed device designed to provide filtered DC power and battery-based operations to other modules of the system. A wide-range filtered DC power input 92 is located on the front of the module, as is a series of status LEDs 98. It features top-mounted posts 96 allowing the module to be attached to the underside of other modules and a power transfer connector 94 located on the top of the module to provide filtered DC power to modules to which it is attached. The battery module accepts a wide range of DC voltages to charge the battery. The battery module is also capable of recharging and powering the system simultaneously.

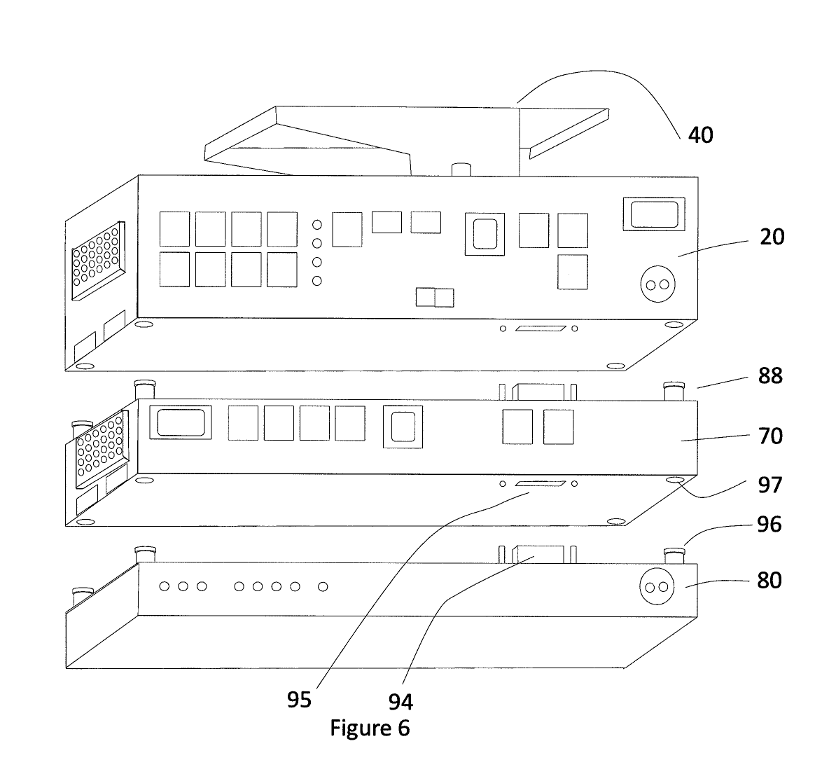

The system shown in FIG. 6 depicts how various modules may be attached in a stacked fashion to form a single unit. As can be seen, the posts of a lower module fit within a recess in the upper module. The mechanical connectors on the side of the upper module are manipulated to cause an element to engage the posts to releasable secure the two modules together. In addition, the power transfer connectors allow power to flow from a lower module to an upper module. In this manner, power from the battery module can supply power to the secondary and main modules.

While the invention has been described with reference to a preferred embodiment, variations and modifications would be apparent to one of ordinary skill in the art. The invention encompasses such variations and modifications.

We claim:

1. A communication device, comprising:
a top wall, a bottom wall and a plurality of side walls including a front wall;
a plurality of input ports, at least one input port provided with power;
a least one output port;
a printed circuit board; and
a plurality of components board mounted on the printed circuit board, the components including:
an input/output panel;
a switch;
a router;
a power supply; and
a power-over-ethernet injector;
wherein the components are electrically connected to one another through a backplane on the printed circuit board.

2. The communication device of claim 1, wherein the plurality of input ports comprises a plurality of RJ-45 input ports, some of the RJ-45 input ports being provided with power-over-ethernet (PoE).

3. The communication device of claim 2, wherein the switch comprises:
a first switch electrically connected to the input ports not provided with power; and
a second switch electrically connected to the input ports provided with power.

4. The communication device of claim 2, wherein the input ports further comprise at least one fiber optic ports.

5. The communication device of claim 1, wherein the dimensions of the device are no greater than eleven inches by five inches by three inches.

6. The communication device of claim 1, wherein the device has a volume no greater than one hundred sixty five cubic inches.

7. The communication device of claim 1, further comprising a zeroizartion switch for clearing the memory of the router.

8. The communication device of claim 1, further comprising an accelerator.

9. The communication device of claim 8, further comprising an acceleration bypass switch.

10. A communication system, comprising:
a main module, the main module comprising:
a top wall, a bottom wall and a plurality of side walls including a front wall;
a plurality of input ports, at least one input port provided with power;
a least one output port;
a printed circuit board; and
a plurality of components board mounted on the printed circuit board, the components including:
an input/output panel;
a switch;
a router;
a power supply; and
a power-over-ethernet injector;
wherein the components are electrically connected to one another through a backplane on the printed circuit board; and
a battery module, the battery module having a power transfer connector for supplying power to the main module.

11. The communication system of claim 9, further comprising:
a secondary module, the secondary module comprising a plurality of input ports, at least one output port, the secondary module receiving power from the battery module and having a power transfer connector to transfer power to the main module.

12. The communication system of claim 10, further comprising an encryptor mounted to said main module.

13. The communication device of claim 10, wherein the plurality of input ports of the main module comprises eight RJ-45 input ports, three of the RJ-45 input ports being provided with power.

14. The communication device of claim 13, wherein the switch comprises:
a first switch electrically connected to the input ports not provided with power; and
a second switch electrically connected to the input ports provided with power.

15. The communication device of claim 13, wherein the input ports of the main module further comprise two fiber optic ports.

16. The communication device of claim 10, wherein the dimensions of the main module are no greater than eleven inches wide by five inches deep by three inches in height.

17. The communication device of claim 10, wherein the main module has a volume no greater than one hundred sixty five cubic inches.

18. The communication device of claim 10, the main module further comprises a zeroizartion switch for clearing the memory of the router.

19. The communication device of claim 10, further comprising an accelerator.

20. The communication device of claim 19, the main module further comprises an acceleration bypass switch.
